(19) United States
(12) Patent Application Publication
(10) Pub. No.: US 2025/0255074 A1
(43) Pub. Date: Aug. 7, 2025

(54) SEMICONDUCTOR DEVICE

(71) Applicant: UNIKORN SEMICONDUCTOR CORPORATION, Hsinchu (TW)

(72) Inventors: Chih-Ming SHEN, Hsinchu (TW); Chia-Yin HSU, Hsinchu (TW); Shih-I CHEN, Hsinchu (TW); Ching-En HUANG, Hsinchu (TW); Hao-Ming KU, Hsinchu (TW); Tzu-Ling YANG, Hsinchu (TW); Jui-Hsien TSENG, Hsinchu (TW)

(21) Appl. No.: 19/045,836

(22) Filed: Feb. 5, 2025

(30) Foreign Application Priority Data
Feb. 6, 2024 (TW) 113104652

(51) Int. Cl. H10H 29/80; H10H 29/01; H10H 29/14; H10H 29/85

(52) U.S. Cl. CPC H10H 29/8321; H10H 29/142; H10H 29/8421; H10H 29/032; H10H 29/857

(57) ABSTRACT

A semiconductor device is provided. The semiconductor device includes a semiconductor structure, an outer electrode structure, an inner electrode structure, and an adjustment structure. The semiconductor structure includes a first portion and a second portion, wherein the second portion is on the first portion and includes an active region. The outer electrode structure is on the first portion of the semiconductor structure and has a first top surface. The inner electrode structure is on the second portion of the semiconductor structure and has a second top surface. The adjustment structure covers the semiconductor structure and is in contact with the outer electrode structure and the inner electrode structure, and the adjustment structure has a third top surface. The third top surface is substantially coplanar with either the first top surface, the second top surface, or both.

### CROSS REFERENCE TO RELATED APPLICATIONS

This application claims priority of Taiwan Patent Application No. 113104652, filed on Feb. 6, 2024, the entirety of which is incorporated by reference herein.

### BACKGROUND OF THE DISCLOSURE

### Field of the Disclosure

The present disclosure relates to a semiconductor device, and, in particular, to a semiconductor light-emitting diode device.

### Description of the Related Art

With the rapid development of electronic devices, various elements in the electronic devices are gradually scaled down to meet various needs. Taking light-emitting diode devices as an example, when their sizes are scaled down, traditional manufacturing methods are limited, resulting in device failure and yield loss. Therefore, although the existing light-emitting diode devices have largely met their intended purposes, they do not meet requirements in all respects. Therefore, there are still some problems that need to be overcome regarding the light-emitting diode devices.

### BRIEF SUMMARY OF THE DISCLOSURE

In some embodiments of the present disclosure, a semiconductor device is provided. The semiconductor device includes a semiconductor structure, an outer electrode structure, an inner electrode structure, and an adjustment structure. The semiconductor structure includes a first portion and a second portion on the first portion, wherein the second portion includes an active region. The outer electrode structure is on the first portion of the semiconductor structure and has a first top surface. The inner electrode structure is on the second portion of the semiconductor structure and has a second top surface. The adjustment structure covers the semiconductor structure and is in contact with the outer electrode structure and the inner electrode structure, and the adjustment structure has a third top surface. The first top surface and the third top surface are substantially coplanar, and/or the second top surface and the third top surface are substantially coplanar.

The semiconductor device of the present disclosure can be applied in a variety of electronic devices. In order to make the features and advantages of the present disclosure more comprehensible, various embodiments are specially cited below, together with the accompanying drawings, to be described in detail as follows.

### BRIEF DESCRIPTION OF THE DRAWINGS

Aspects of the present disclosure are best understood from the following detailed description when read with the accompanying FIGS. It should be noted that, in accordance with the standard practice in the industry, various features are not drawn to scale. In fact, the dimensions of the various features may be arbitrarily increased or reduced for clarity of discussion.

FIG. 1 is a cross-sectional view showing the semiconductor device according to some embodiments of the present disclosure.

FIG. 2 is a top view showing the semiconductor device according to some embodiments of the present disclosure.

FIG. 3 is a cross-sectional view showing the semiconductor device according to further embodiments of the present disclosure.

FIGS. 4A to 4D are cross-sectional views of the semiconductor device at different process stages according to further embodiments of the present disclosure.

FIG. 5A is a cross-sectional view showing the semiconductor device according to further embodiments of the present disclosure.

FIG. 5B is a cross-sectional view showing the semiconductor device according to further embodiments of the present disclosure.

FIG. 6 is a cross-sectional view showing the semiconductor device according to further embodiments of the present disclosure.

FIG. 7 is a cross-sectional view showing the semiconductor device according to further embodiments of the present disclosure.

FIG. 8 is a cross-sectional view showing the semiconductor device according to further embodiments of the present disclosure.

FIG. 9A is a cross-sectional view showing the semiconductor device according to further embodiments of the present disclosure.

FIG. 9B is a top view showing the semiconductor device according to further embodiments of the present disclosure.

FIG. 10 is a cross-sectional view showing the semiconductor device according to further embodiments of the present disclosure.

FIG. 11 is a cross-sectional view showing the semiconductor device according to further embodiments of the present disclosure.

FIG. 12 is a cross-sectional view showing the semiconductor device according to further embodiments of the present disclosure.

FIG. 13 is a top view showing the semiconductor device according to further embodiments of the present disclosure.

FIG. 14 is a cross-sectional view showing the semiconductor device according to further embodiments of the present disclosure.

FIG. 15 is a cross-sectional view showing the semiconductor device according to further embodiments of the present disclosure.

### DETAILED DESCRIPTION OF THE DISCLOSURE

The following disclosure provides many different embodiments or examples for implementing the various features of the provided device. Specific examples of features and their configurations are described below to simplify the embodiments of the present disclosure, but certainly not to limit the present disclosure. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially related terms may be used here, such as “under”, “below”, “lower”, “on”, “above”, and similar terms. These spatial terms are used to describe the relationship between one element or feature and other elements or features as shown in the figures. These spatial terms are intended to cover the various orientations of the device in use or operation, in addition to the orientation depicted in the figures. For example, if the device in the figures is turned over, elements or features described as “lower than” or “beneath” other elements or features would then be described as “above” the other elements or features. Therefore, the exemplary term “below” can have both the orientations of “above” and “below”. When the device is rotated 90° or at any other orientation, the spatially related terms used herein may be interpreted similarly to the rotated orientation.

In addition, ordinal numbers such as “first”, “second”, and the like used in the specification and claims are configured to modify different features or to distinguish different embodiments or ranges, rather than to limit the number, the upper or lower limits of features, and are not intended to limit the order of manufacture or arrangement of features.

Unless otherwise defined, all terms (including technical and scientific terms) used herein have the same meaning as commonly understood by one of ordinary skill in the art. It should be understood that these terms, such as those defined in commonly used dictionaries, should be interpreted as having meanings consistent with the background or context of the related technology and the present disclosure, and should not be interpreted in an idealized or overly formal manner, unless otherwise specified in the embodiments of the present disclosure.

The semiconductor device can be a semiconductor optoelectronic device, such as light-emitting diode device. In light-emitting diode devices, electrode structures (such as p-type electrode(s) and n-type electrode(s)) are usually formed by dry etching. However, when manufacturing the micro light-emitting diodes, the dry etching process cannot provide high enough accuracy, resulting in a height difference between the p-type electrode and the n-type electrode. This height difference will make the light-emitting diode devices difficult to be connected to a circuit by a subsequent mass transfer process. In some cases, this height difference can even lead to unstable electrical connections between devices, resulting in the failure of devices. Furthermore, a planarization process can be carried out after electroplating metal onto the conductive layer on the die by chemical-mechanical planarization (CMP), and the planarization process are beneficial to the subsequent bonding process.

However, in some cases, the planarization process can even damage an insulating structure on the die, resulting in device failure. In addition, since the die spacing of micro light-emitting diode devices is extremely small, it is also easy to produce crosstalk between two dies.

In order to solve at least the above-mentioned problems, the present disclosure provides a semiconductor device in which top surfaces of electrodes are substantially coplanar. In this way, the semiconductor device of the present disclosure can be firmly electrically connected to other electronic devices, thereby effectively improving the process yield and device reliability. In the following, various embodiments of semiconductor devices are provided to make the technical features and beneficial effects of the present disclosure clearer and easier to understand.

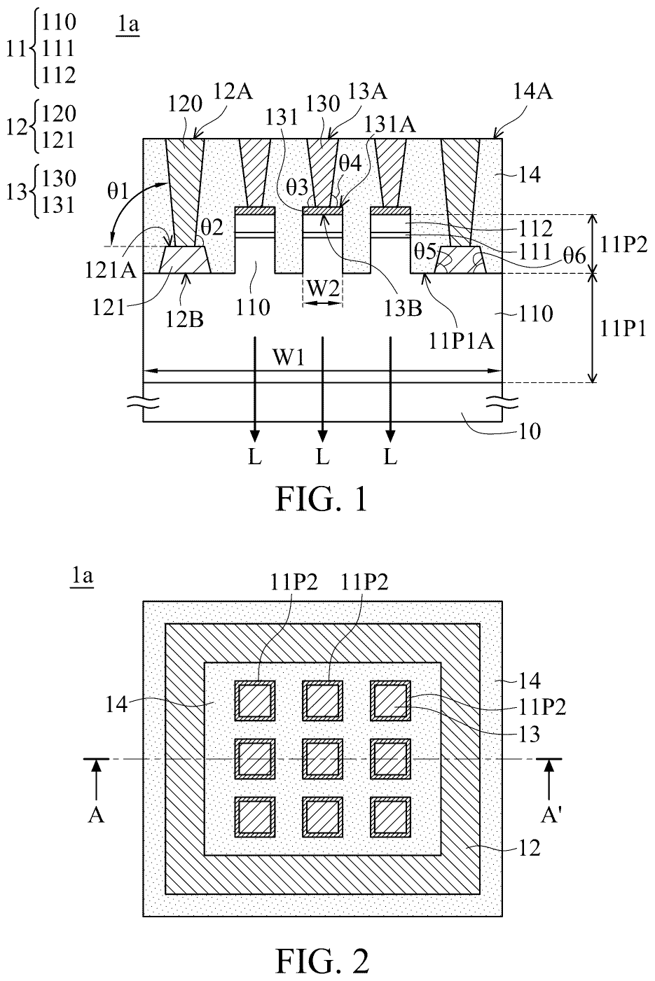

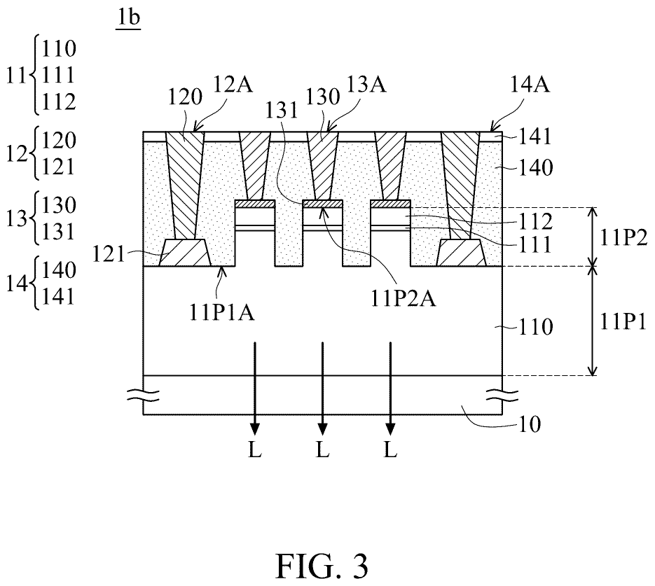

FIGS. 1 and 2 are a cross-sectional view and a top view showing the semiconductor device 1a according to some embodiments of the present disclosure. Specifically, FIG. 1 can be a cross-sectional view along the line A-A′ in FIG. 2. In this embodiment, the semiconductor device 1a may be a light-emitting diode device. The semiconductor device 1a includes a semiconductor structure 11, an outer electrode structure 12, an inner electrode structure 13, and an adjustment structure 14. The outer electrode structure 12, the inner electrode structure 13, and the adjustment structure 14 are on the semiconductor structure 11. In some embodiments, the semiconductor device 1a may optionally include a substrate 10, and the semiconductor structure 11 is on the substrate 10.

As shown in FIGS. 1 and 2, the semiconductor structure 11 includes a first portion 11P1 and a plurality of second portions 11P2 that are on the first portion 11P1. From the top view of the semiconductor device 1a, the second portions 11P2 may be arranged on the first portion 11P1 in a one-dimensional or two-dimensional manner, and the arrangement may be a regular arrangement, a closest packing arrangement, or an irregular arrangement. In some embodiments, the second portions 11P2 are regularly arranged on the first portion 11P1 in a two-dimensional array. The first portion 11P1 includes a width W1, and one of the plurality of second portions 11P2 includes a width W2 smaller than the width W1. Each second portion 11P2 and the corresponding first portion 11P1 below it is a light-emitting unit, and each light-emitting unit may emit light L. The light emitted by each light-emitting unit may be the same or different. For example, the second portions 11P2 all emit blue light, green light, or red light. Alternatively, one of the second portions 11P2 may emit blue light, another may emit green light, and still another may emit red light.

In some embodiments, the first portion 11P1 includes a part of the first semiconductor layer 110. The second portion 11P2 includes a part of the first semiconductor layer 110, an active region 111, and a second semiconductor layer 112, which are sequentially stacked. The first semiconductor layer 110 has a first conductivity type, and the second semiconductor layer 112 has a second conductivity type different from the first conductivity type. For example, the first semiconductor layer 110 is n-type and the second semiconductor layer 112 is p-type. Alternatively, the first semiconductor layer 110 is p-type and the second semiconductor layer 112 is n-type. Therefore, the first semiconductor layer 110 and the second semiconductor layer 112 may respectively provide electrons and holes, or provide holes and electrons.

As shown in FIG. 1, the outer electrode structure 12 is on the first portion 11P1 of the semiconductor structure 11 but not on the second portion 11P2, and the outer electrode structure 12 is electrically connected to the first semiconductor layer 110. In some embodiments, the outer electrode structure 12 may include the first conductive layer 120 and the second conductive layer 121 under the first conductive layer 120, and the second conductive layer 121 is in direct contact with the first semiconductor layer 110. In the cross-sectional view, the first conductive layer 120 has an inverted trapezoid shape that gradually narrows from top to bottom (that is, from the side away from the substrate 10 to the side adjacent to the substrate 10), and the second conductive layer 121 has a positive trapezoidal shape that gradually becomes wider from top to bottom.

As shown in FIG. 1, the inner electrode structure 13 is on the second portion 11P2 of the semiconductor structure 11 and is electrically connected to the second semiconductor layer 112. In some embodiments, the inner electrode structure 13 includes the third conductive layer 130. In the cross-sectional view, the third conductive layer 130 has an inverted trapezoid shape that gradually narrows from top to bottom. In other embodiments, the semiconductor device 1a may optionally include the fourth conductive layer 131 under the third conductive layer 130, and the fourth conductive layer 131 is in direct contact with the second semiconductor layer 112 of the second portion 11P2. The fourth conductive layer 131 may completely cover or partially cover a top surface of the second semiconductor layer 112. In this embodiment, the fourth conductive layer 131 is between the third conductive layer 130 and the second semiconductor layer 112.

In some embodiments, the outer electrode structure 12 has a first top surface 12A and a first bottom surface 12B opposite to the first top surface 12A, and the first top surface 12A is farther from the semiconductor structure 11 than the first bottom surface 12B. The inner electrode structure 13 has a second top surface 13A and a second bottom surface 13B opposite to the second top surface 13A, and the second top surface 13A is farther from the semiconductor structure 11 than the second bottom surface 13B. The first bottom surface 12B of the outer electrode structure 12 is not coplanar with the second bottom surface 13B of the inner electrode structure 13. In other words, the top surface 11P1A of the first portion 11P1 and a top surface of the second portion 11P2 are not coplanar. Specifically, the first bottom surface 12B of the outer electrode structure 12 is on the first portion 11P1, and the second bottom surface 13B of the inner electrode structure 13 is on the second portion 11P2, so the first bottom surface 12B is lower than the second bottom surface 13B. On the other hand, the first top surface 12A of the outer electrode structure 12 and the second top surface 13A of the inner electrode structure 13 are substantially coplanar.

As shown in FIGS. 1 and 2, in the top view, the semiconductor device 1a includes the plurality of inner electrode structures 13, wherein each inner electrode structure 13 is on the second portion 11P2. The outer electrode structure 12 surrounds the inner electrode structures 13. FIG. 2 shows nine inner electrode structures 13 arranged in a 3×3 array. In other embodiments, other arrays may be used to provide more or less than nine inner electrode structures 13. In this embodiment, the outer electrode structure 12 surrounds the inner electrode structures 13. The top-view shape of each inner electrode structure 13 is rectangular, and the top-view shape of the outer electrode structure 12 is annular. In some embodiments, the top-view shape of each inner electrode structure 13 may be circular or other polygons.

As shown in FIG. 1, in the cross-sectional view, the adjustment structure 14 covers the semiconductor structure 11, side surfaces of the outer electrode structure 12 and the inner electrode structures 13, and is in contact with the outer electrode structure 12 and the inner electrode structures 13. The adjustment structure 14 has a third top surface 14A away from the semiconductor structure 11, and the third top surface 14A of the adjustment structure 14 may be selectively coplanar with the first top surface 12A and/or the second top surface 13A. Alternatively, in another embodiment, the third top surface 14A is higher than the first top surface 12A and/or the second top surface 13A.

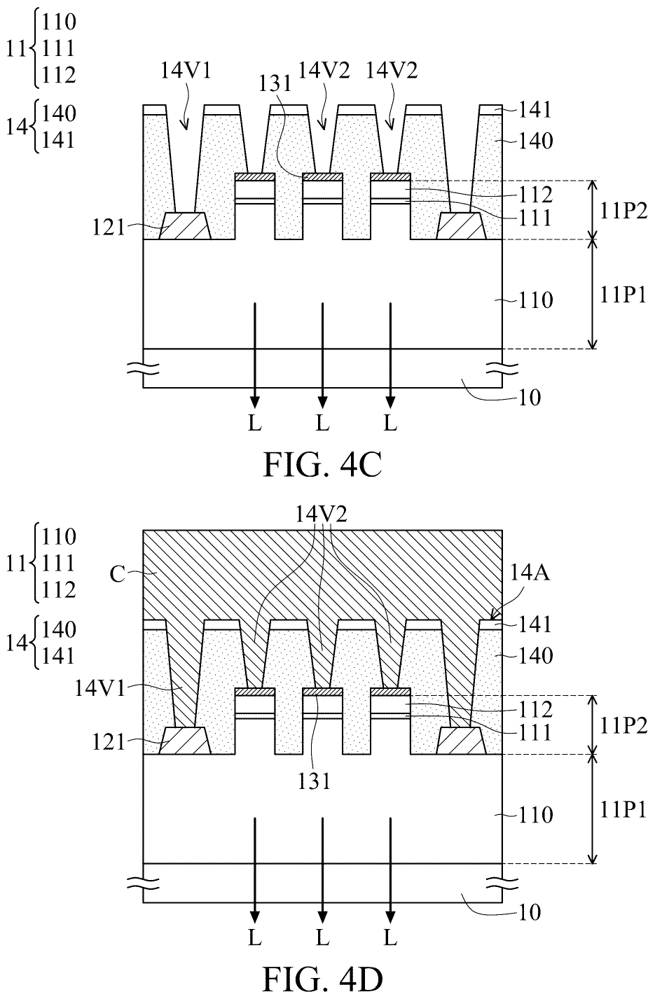

As shown in FIG. 1, in some embodiments, an angle θ1 or an angle θ2 between an outer surface of the first conductive layer 120 of the outer electrode structure 12 and the first top surface 12A of the second conductive layer 121 is between 70° and 85°. When the area of the first top surface 12A is fixed, if the angle θ1 or the angle θ2 is less than 70°, the bottom surface area of the first conductive layer 120 is too small. Therefore, the electrical connection between the first conductive layer 120 and the underlying elements (for example, the second conductive layer 121 or the fifth conductive layer 122 mentioned hereinafter) is poor. On the contrary, if the angle θ1 or the angle θ2 is greater than 85°, the first conductive layer 120 can be damaged or become incomplete after the step of depositing metal in an opening of the adjustment structure 14 (as shown in FIG. 4C).

In some embodiments, an angle θ3 or an angle θ4 between an outer surface of the third conductive layer 130 of the inner electrode structure 13 and the top surface 131A of the fourth conductive layer 131 is between 70° and 85°. When the area of the second top surface 13A is fixed, if the angle θ3 or the angle θ4 is less than 70°, the bottom surface area of the third conductive layer 130 is too small. Therefore, the electrical connection between the third conductive layer 130 and the underlying elements (for example, the fourth conductive layer 131 or the sixth conductive layer 132 mentioned hereinafter) is poor. On the contrary, if the angle θ3 or the angle θ4 is greater than 85°, the third conductive layer 130 can be damaged or become incomplete after the step of depositing metal in the opening of the adjustment structure 14 (as shown in FIG. 4C).

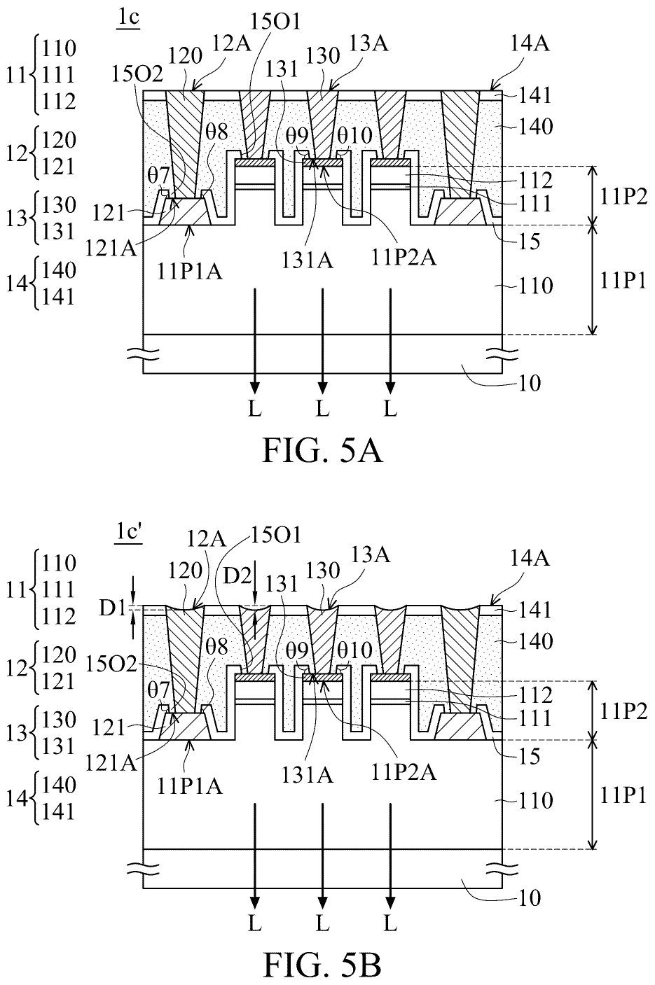

In some embodiments, an angle θ5 or an angle θ6 between an inner surface of the second conductive layer 121 of the outer electrode structure 12 and the top surface 11P1A of the first portion 11P1 is between 30° and 65°. When the area of the first bottom surface 12B is fixed, if the angle θ5 or the angle θ6 is less than 30°, the top surface 121A of the second conductive layer 121 is too small. Therefore, the subsequent processes will be more difficult. On the contrary, when the angle θ5 or the angle θ6 is greater than 65°, it may cause the adjustment structure 14 on the second conductive layer 121 (and an insulating structure 15 that may be disposed thereon, as shown in FIG. 5A) to be damaged during the deposition process.

In this embodiment, the substrate 10 has a high transmittance for the light emitted by the active region 111. For example, the substrate 10 includes a transparent material, and the transparent material has a transmittance of the light emitted by the active region 111 higher than 85%. In some embodiments, the substrate 10 includes silicon (Si), diamond (C), silicon carbide (SiC), sapphire, glass, gallium oxide (Ga₂O₃), gallium nitride (GaN), aluminum gallium nitride (AlGaN), aluminum nitride (AlN), gallium phosphide (GaP), gallium arsenide (GaAs), aluminum gallium arsenide (AlGaAs), or a combination thereof. For example, the substrate 10 may be a silicon carbide substrate, a sapphire substrate, or a gallium nitride substrate.

In some embodiments, the first semiconductor layer 110, the active region 111, and the second semiconductor layer 112 include III-V semiconductor materials, such as aluminum (Al), gallium (Ga), arsenic (As), phosphorus (P), or indium (In). For example, the III-V semiconductor material can be a binary compound semiconductor (such as GaAs, GaP, GaN, or InP), a ternary compound semiconductor (such as InGaAs, AlGaAs, GalnP, AlInP, InGaN, or AlGaN), or a quaternary compound semiconductor (such as AlGaInAs, AlGaInP, AlInGaN, InGaAsP, InGaAsN, or AlGaAsP).

In some embodiments, a doping process may be performed on the first semiconductor layer 110 and the second semiconductor layer 112, so that the first semiconductor layer 110 includes a first dopant and thus has a first conductivity type, and the second semiconductor layer 112 includes a second dopant and thus has a second conductivity type. For example, the doping process may include in-situ doping during epitaxial growth, implanting after epitaxial growth, or a combination thereof. In some embodiments, the first dopant or the second dopant may be magnesium (Mg), zinc (Zn), silicon (Si), carbon (C), or tellurium (Te).

In some embodiments, the active region 111 can emit light, and the light emitted by the active region 111 includes visible light or invisible light. The wavelength of the light emitted by the active region 111 depends on the material composition of the active region 111. For example, when the material of the active region 111 includes the InGaN series, the active region 111 may emit blue light or deep blue light with a peak wavelength of 400 nm to 490 nm, green light with a peak wavelength of 490 nm to 550 nm, or red light with a peak wavelength of 560 nm to 650 nm. When the material of the active region 111 includes the AlGaN series, the active region 111 may emit ultraviolet light with a peak wavelength of 250 nm to 400 nm. When the material of the active region 111 includes the InGaAs series, InGaAsP series, AlGaAs series, or AlGaInAs series, the active region 111 may emit infrared light with a peak wavelength of 700 nm to 1700 nm. When the material of the active region 111 includes InGaP series or AlGaInP series, the active region 111 may emit red light with a peak wavelength of 610 nm to 700 nm, or yellow light with a peak wavelength of 530 nm to 600 nm.

In some embodiments, the semiconductor material structure may be formed on the substrate 10 through a deposition process or epitaxial process. The deposition process may include physical vapor deposition (PVD), atomic layer deposition (ALD), metal-organic chemical vapor deposition (MOCVD), or a combination thereof. The epitaxy process may include molecular beam epitaxy (MBE), liquid phase epitaxy (LPE), vapor phase epitaxy (VPE), atomic layer epitaxy (ALE), or a combination thereof. Then, the semiconductor material structure may be wet etched, dry etched, or a combination thereof to remove part of the semiconductor material structure to form the first portion 11P1 and the plurality of second portions 11P2.

In some embodiments, the first conductive layer 120 or the second conductive layer 121 may include conductive material. For example, the conductive material may include metals, metal compounds, or a combination thereof. In some embodiments, the metal may be tin (Sn), copper (Cu), gold (Au), silver (Ag), nickel (Ni), indium (In), platinum (Pt), palladium (Pd), iridium (Ir), titanium (Ti), chromium (Cr), tungsten (W), aluminum (Al), molybdenum (Mo), magnesium (Mg), zinc (Zn), germanium (Ge), beryllium (Be), or alloys thereof. In some embodiments, the metal compound may be tantalum nitride (TaN), titanium nitride (TiN), tungsten silicide (WSi₂), indium tin oxide (ITO), indium oxide (InO), tin oxide (SnO), Cadmium tin oxide (CTO), antimony tin oxide (ATO), aluminum zinc oxide (AZO), zinc tin oxide (ZTO), gallium zinc oxide (GZO), indium tungsten oxide (IWO), zinc oxide (ZnO), indium oxide Zinc (IZO), or indium gallium zinc oxide (IGZO). In some embodiments, the material of the first conductive layer 120 may be the same as or different from the material of the second conductive layer 121. For example, the material of the first conductive layer 120 includes copper (Cu), and the material of the second conductive layer 121 includes gold (Au), germanium (Ge), beryllium (Be), or alloys thereof.

In some embodiments, the first conductive layer 120 or the second conductive layer 121 may be formed by an electroplating process, a physical vapor deposition process (e.g., a sputtering process), a chemical vapor deposition process, a combination thereof, or other suitable processes. In some embodiments, the first conductive layer 120 and the second conductive layer 121 may be formed by different processes.

In some embodiments, the third conductive layer 130 or the fourth conductive layer 131 may include conductive material as mentioned above. In some embodiments, the material of the third conductive layer 130 may be the same as or different from the material of the fourth conductive layer 131. For example, the material of the third conductive layer 130 includes copper (Cu), and the material of the fourth conductive layer 131 includes indium tin oxide (ITO).

In some embodiments, the third conductive layer 130 or the fourth conductive layer 131 may be formed by an electroplating process, a physical vapor deposition process (e.g., a sputtering process), a chemical vapor deposition process, or a combination thereof. In some embodiments, the third conductive layer 130 and the fourth conductive layer 131 may be formed by different processes.

In some embodiments, the adjustment structure 14 may include non-conductive material. For example, the non-conductive material may include oxide material, non-oxide material, or a combination thereof. For example, the oxide material may include silicon dioxide (SiO₂), titanium dioxide (TiO₂), tantalum pentoxide (Ta₂O₅), aluminum oxide (Al₂O₃), etc. The non-oxide material may include nitride Silicon (SiNx), benzocyclobutene (BCB), cycloolefin copolymer (COC), polyimide (PI), fluorocarbon polymer, calcium fluoride (CaF₂), or magnesium fluoride (MgF₂). In some embodiments, the adjustment structure 14 may also include an opaque material to absorb or reflect light from adjacent active regions 111 to avoid interference between adjacent active regions 111. For example, the opaque material may include organic glue containing carbon, graphene, and/or metal particles. The organic glue includes silicone.

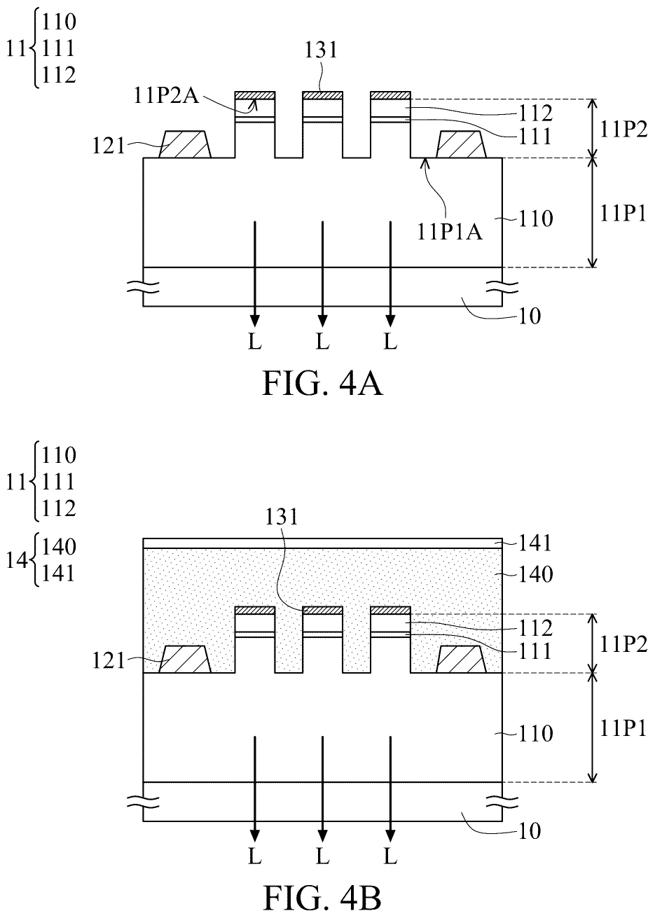

FIG. 3 is a cross-sectional view showing the semiconductor device 1b according to further embodiments of the present disclosure. Compared with the embodiment in FIG. 1, the adjustment structure 14 of the semiconductor device 1b in FIG. 3 includes a first sublayer 140 and a second sublayer 141 on the first sublayer 140. The third top surface 14A is a top surface of the second sublayer 141. In some embodiments, a hardness or a Young's modulus of the first sublayer 140 may be different from that of the second sublayer 141. For example, the Young's modulus or hardness of the second sublayer 141 is higher than that of the first sublayer 140. The first sublayer 140 may be used to reflect the light generated by the light-emitting units to avoid cross talk between the light-emitting units, and the second sublayer 141 may be used as a polishing stop layer for the planarization process.

In some embodiments, the first sublayer 140 or the second sublayer 141 may include the above-mentioned non-conductive material, and the material of the first sublayer 140 is different from the material of the second sublayer 141. For example, the material of the first sublayer 140 may include benzocyclobutene (BCB), and the material of the second sublayer 141 may include silicon dioxide (SiO₂). In one embodiment, the thickness of the second sublayer 141 may be less than or equal to the thickness of the first sublayer 140. For example, the thickness of the first sublayer 140 may be 0.1 μm to 5 μm, and the thickness of the second sublayer 141 may be 0.01 μm to 1 μm.

In detail, FIGS. 4A to 4D are schematic diagrams of the structure of the semiconductor device 1b during a part of the process. First, as shown in FIG. 4A, the semiconductor material structure is formed on the substrate 10 and a part of the semiconductor material structure is removed to form the first portion 11P1 and the plurality of second portions 11P2. The second conductive layer 121 is formed on the top surface 11P1A of the first portion 11P1, and the fourth conductive layer 131 is formed on the top surface 11P2A of each second portion 11P2, as shown in FIG. 4A.

Next, as shown in FIG. 4B, the adjustment structure 14 is formed to cover the semiconductor structure 11. In detail, the adjustment structure 14 includes the first sublayer 140 and the second sublayer 141 which are sequentially stacked on the semiconductor structure 11.

As shown in FIG. 4C, the first hole 14V1 and the plurality of second holes 14V2 penetrating the first sublayer 140 and the second sublayer 141 are formed in the adjustment structure 14. The second conductive layer 121 is exposed through the first hole 14V1, and the plurality of fourth conductive layers 131 are exposed through the plurality of second holes 14V2. The first hole 14V1 surrounds the plurality of second holes 14V2 (not shown).

Then, as shown in FIG. 4D, the conductive structure C is filled into the first hole 14V1 and the plurality of second holes 14V2, and a planarization process is performed to remove a part of the conductive structure C above the second sublayer 141, so as to form the first conductive layer 120 in the first hole 14V1, and to from the plurality of third conductive layers 130 in the plurality of second holes 14V2. The semiconductor device 1b as shown in FIG. 3 is completed. In one embodiment, the material of the conductive structure C may include a first metal layer and a second metal layer stacked on the first metal layer (not shown). For example, the first metal layer may be formed on the first hole 14V1, the second hole 14V2, and/or the third top surface 14A of the adjustment structure 14 by evaporation or sputtering, and the second metal layer may be formed on the first metal layer by electroplating. The material of the conductive structure C may be tin (Sn), copper (Cu), gold (Au), silver (Ag), nickel (Ni), indium (In), titanium (Ti), tungsten (W), aluminum (Al), zinc (Zn), germanium (Ge), or alloys thereof.

In this embodiment, the planarization process may include chemical mechanical polishing (CMP). Specifically, since the high hardness of the second sublayer 141, the second sublayer 141 may serve as a polishing stop layer to protect the first sublayer 141 from damaging during the polishing process. The first top surface 12A of the outer electrode structure 12 formed through the above process may be substantially coplanar with the second top surface 13A of the inner electrode structure 13. In this embodiment, the third top surface 14A of the adjustment structure 14 is also substantially coplanar with the first top surface 12A and/or the second top surface 13A. In an embodiment in which the semiconductor device 1a does not have the second sublayer 141 (as shown in FIG. 1), the planarization process may be completed in a specific interval by adjusting the polishing process time or real-time monitoring during the polishing process, thereby making the first top surface 12A of the outer electrode structure 12 substantially coplanar with the second top surface 13A of the inner electrode structure 13.

FIG. 5A is a cross-sectional view showing the semiconductor device 1c according to further embodiments of the present disclosure. Compared with the embodiment in FIG. 3, the semiconductor device 1c further includes the insulating structure 15. The insulating structure 15 is conformally disposed on the semiconductor structure 11. Specifically, the insulating structure 15 covers the semiconductor structure 11, multiple side surfaces and a part of the upper surface of the second conductive layer 121 of the outer electrode structure 12, and multiple side surfaces and a part of the upper surface of the fourth conductive layer 131 of the inner electrode structure 13. The insulating structure 15 has a plurality of first openings 1501 on the second portions 11P2 and a second opening 1502 on the second conductive layer 121.

As shown in FIG. 5A, in some embodiments, the insulating structure 15 on the second conductive layer 121 has an inner surface, and an angle θ7 and an angle θ8 between the inner surface and the top surface 121A of the second conductive layer 121 are between 30° and 65°. In some embodiments, an angle θ9 and an angle θ10 between the inner surface of the insulating structure 15 on the fourth conductive layer 131 and the top surface 131A of the fourth conductive layer 131 are between 30° and 65°.

In some embodiments, the insulating structure 15 may include a single layer or a multi-layer stack of dielectric materials. For example, the dielectric material may include oxides, nitrides, polymer materials, a combination thereof, or other suitable dielectric materials, such as silicon dioxide (SiO₂) and silicon nitride (SiₓN_{y}). The insulating structure 15 may include a distributed Bragg reflector structure (DBR) to allow light to be emitted in a direction away from the outer electrode structure 12 and the inner electrode structure 13, so as to prevent the lights emitted by the plurality of second portions of 11P2 from cross-talking when the semiconductor device 1c is lit up, thereby affecting the luminescence characteristics. In another embodiment, the insulating structure 15 has a reflectivity higher than 80% for the light emitted by the active region 111. For example, the reflectivity is 85% to 100%.

FIG. 5B is a cross-sectional view showing the semiconductor device 1c′ according to further embodiments of the present disclosure. Compared with the embodiment of FIG. 5A, the first top surface 12A of the first conductive layer 120 and the second top surface 13A of the second conductive layer 130 of the semiconductor device 1c′ of FIG. 5B have a concave morphology. In some embodiments, the concave morphology may be a shallow dish-shaped recess, in which a center of the first top surface 12A and/or the second top surface 13A is more concave (i.e., has a deeper depth) than an outer edge. In some embodiments, the concave morphology of the first top surface 12A has a first maximum depth D1, and the concave morphology of the second top surface 13A has a second maximum depth D2. The first maximum depth D1 and the second maximum depth D2 are larger than 0 μm and smaller than 0.5 μm. (0 μm<D1, D2<0.5 μm).

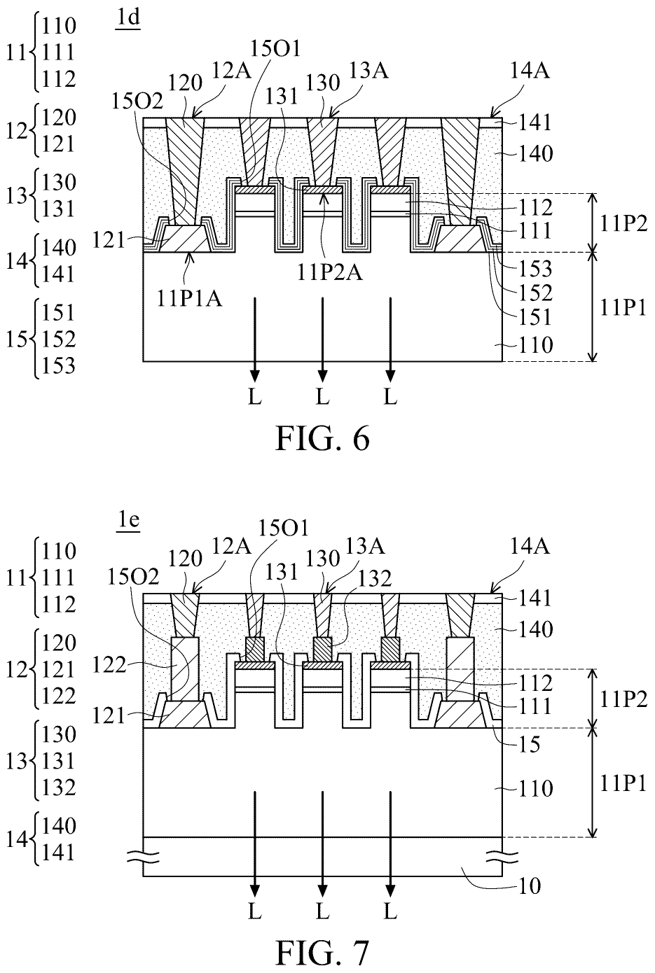

FIG. 6 is a cross-sectional view showing the semiconductor device 1d according to further embodiments of the present disclosure. The insulating structure 15 of the semiconductor device 1d includes a first insulating layer 151, a second insulating layer 153, and a metallic reflective layer 152 between the first insulating layer 151 and the second insulating layer 153. The metallic reflective layer 152 provides high reflectivity to effectively ensure that the light L emitted by the light-emitting unit go toward a direction away from the outer electrode structure 12 and the inner electrode structure 13 (for example, in a direction away from the adjustment structure 14), thereby reducing the probability of light interference between light-emitting units and improving the luminous efficiency of the semiconductor device 1d. The semiconductor device 1d in this embodiment may optionally not have the substrate 10. The materials of the first insulating layer 151 and the second insulating layer 153 may be the dielectric material of the above-mentioned insulating structure 15, such as for example silicon dioxide (SiO₂) and/or silicon nitride (SiₓN_{y}). The material of the metallic reflective layer 152 may include copper (Cu), gold (Au), silver (Ag), nickel (Ni), platinum (Pt), palladium (Pd), titanium (Ti), chromium (Cr), tungsten (W), aluminum (Al), titanium (Ti), germanium (Ge), or alloys thereof. In other embodiments, the metallic reflective layer 152 may further include the function of being electrically connected to the semiconductor structure (not shown). For example, the metallic reflective layer 152 may be selectively electrically connected to the first semiconductor layer 110 or the second semiconductor layer 112. For example, in one embodiment, the metallic reflective layer 152 is in contact with the second conductive layer 121 and is electrically connected to the first semiconductor layer 110, thereby increasing the current distribution uniformity of the semiconductor device.

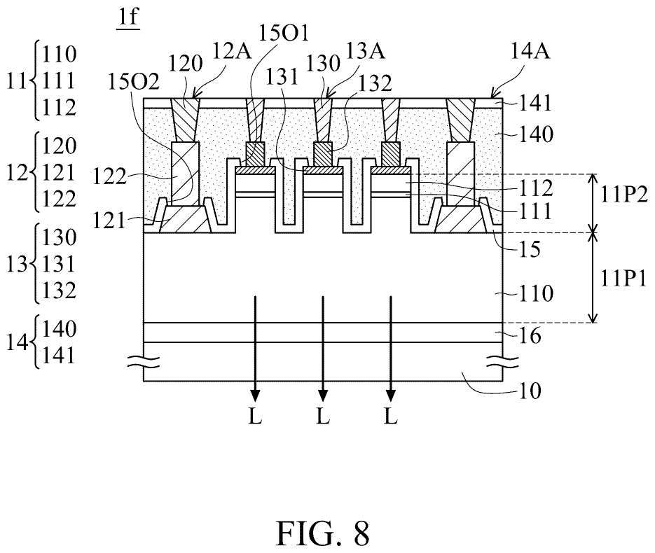

FIG. 7 is a cross-sectional view showing the semiconductor device 1e according to further embodiments of the present disclosure. Compared with the embodiment of FIG. 5A, the outer electrode structure 12 of the semiconductor device 1e in FIG. 6 further includes a fifth conductive layer 122 between the first conductive layer 120 and the second conductive layer 121, and each inner electrode structure 13 further includes a sixth conductive layer 132 between the third conductive layer 130 and the fourth conductive layer 131.

In some embodiments, the fifth conductive layer 122 or the sixth conductive layer 132 may be formed through an electroplating process. The thickness of the fifth conductive layer 122 and the sixth conductive layer 132 may be adjusted to make the upper surface of the fifth conductive layer 122 and the upper surface of the sixth conductive layer 132 substantially coplanar, so as to make the first top surface 12A of the first conductive layer 120 and the second top surface 13A of the third conductive layer 130 subsequently coplanar. In some embodiments, the fifth conductive layer 122 and the second conductive layer 121 may be formed by different processes, and the sixth conductive layer 132 and the fourth conductive layer 131 may also be formed by different processes.

In some embodiments, the fifth conductive layer 122 or the sixth conductive layer 132 may include the above-mentioned conductive materials. In some embodiments, the material of the fifth conductive layer 122 may be the same as the material of the second conductive layer 121. For example, the material of the fifth conductive layer 122 and the material of the second conductive layer 121 may include chromium. In some embodiments, the material of the sixth conductive layer 132 may be the same as the material of the fourth conductive layer 131. For example, the material of the sixth conductive layer 132 and the material of the fourth conductive layer 131 may include indium tin oxide (ITO).

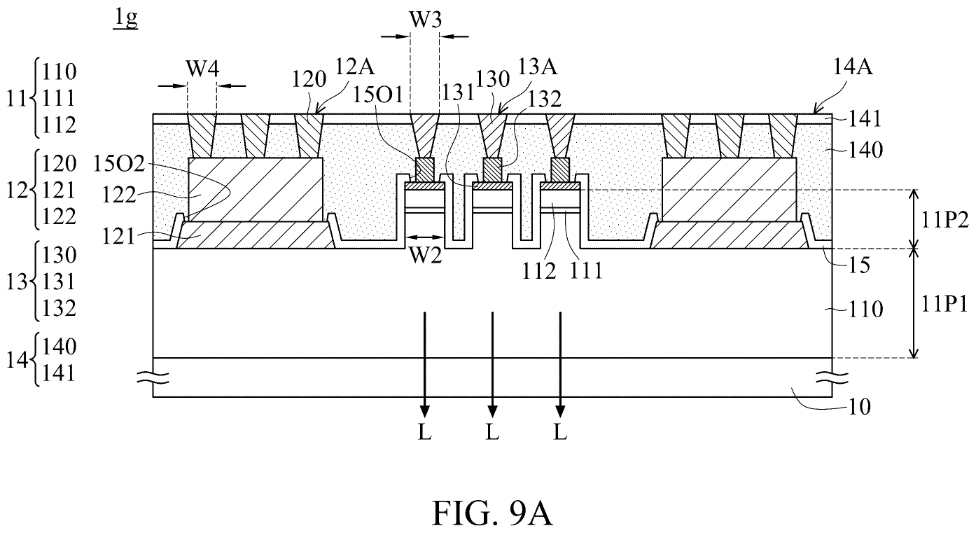

FIG. 8 is a cross-sectional view showing the semiconductor device 1f according to further embodiments of the present disclosure. Compared with the embodiment in FIG. 7, the semiconductor device 1f in FIG. 8 further includes an adhesive layer 16 disposed between the substrate 10 and the semiconductor structure 11. The adhesive layer 16 may include a single layer or multiple layers of dielectric materials alternately stacked. For example, the adhesive layer 16 may be a stack of organic materials and inorganic materials or a stack of inorganic materials, organic materials, and inorganic materials. In one embodiment, the adhesion layer 16 includes oxide, nitride, or polymer material, or a combination thereof, such as silicon dioxide (SiO₂), aluminum oxide (Al₂O₃), silicon nitride (SiₓN_{y}), polyimide (PI), polybenzoxazole (PBO), epoxy, benzocyclobutene (BCB), or a combination thereof.

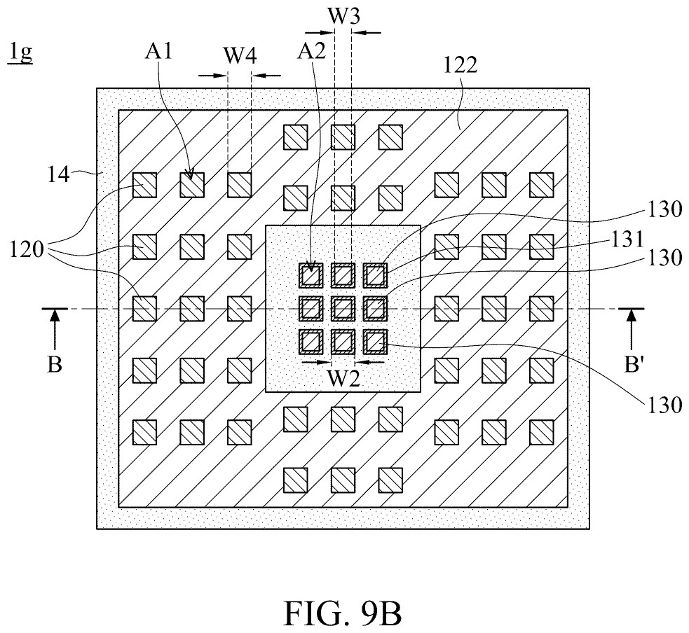

FIG. 9A is a cross-sectional view showing the semiconductor device 1g according to further embodiments of the present disclosure. The components and the connection relationship between components of the semiconductor device 1g is similar to the semiconductor device 1e in FIG. 7. The difference is that the semiconductor device 1g includes the plurality of first conductive layers 120 on the fifth conductive layer 122. FIG. 9B is a top view showing the semiconductor device 1g according to some embodiments of the present disclosure. Specifically, FIG. 9A may be a cross-sectional view along line B-B′ of FIG. 9B. In this embodiment, the top-view shapes of each first conductive layer 120 and each third conductive layer 130 are rectangular. The top-view shape of the fifth conductive layer 122 is annular, and the fifth conductive layer 122 surrounds the plurality of third conductive layers 130. The plurality of first conductive layers 120 are disposed on the fifth conductive layer 122, and the plurality of first conductive layers 120 surround the inner electrode structure 13. Each first conductive layer 120 has a first top view area A1, and each third conductive layer 130 has a second top view area A2 that is substantially equal to the first top view area A1. The terms “substantially equal” means that a difference between the first top view area A1 and the second top view area A2 is less than plus or minus 10%. The difference is calculated as

$$\frac{( A 1 - A 2 )}{A 1} \times 100 \% .$$

The first conductive layer 120 and the third conductive layer 130 are respectively served as the connection components of the outer electrode structure 12 and inner electrode structure 13 to connect the circuit. The uniformity of the first top surface 12A and the second top surface 13A may be increased after a planarization process by making the first conductive layer 120 and the third conductive layer 130 have approximately equal planar areas, so as to make the first top surface 12A and the second top surface 13A are flat planes. Therefore, the yield of the subsequent packaging and bonding process of the semiconductor device 1g can be increased.

In this embodiment, the first conductive layer 120 has a first width W4 and the third conductive layer 130 has a second width W3. The width W2 of the second portion 11P2 of each light-emitting unit is greater than or equal to the first width W4 or/and the second width W3. In this embodiment, the quantity of the plurality of first conductive layers 120 is n1, the quantity of the plurality of third conductive layers 130 is n2, and the semiconductor device 1g has the following characteristics:

$$20 \% \leq \frac{( n 1 \times A 1 + n 2 \times A 2 )}{A 3} \times 100 \% \leq 45 \% .$$

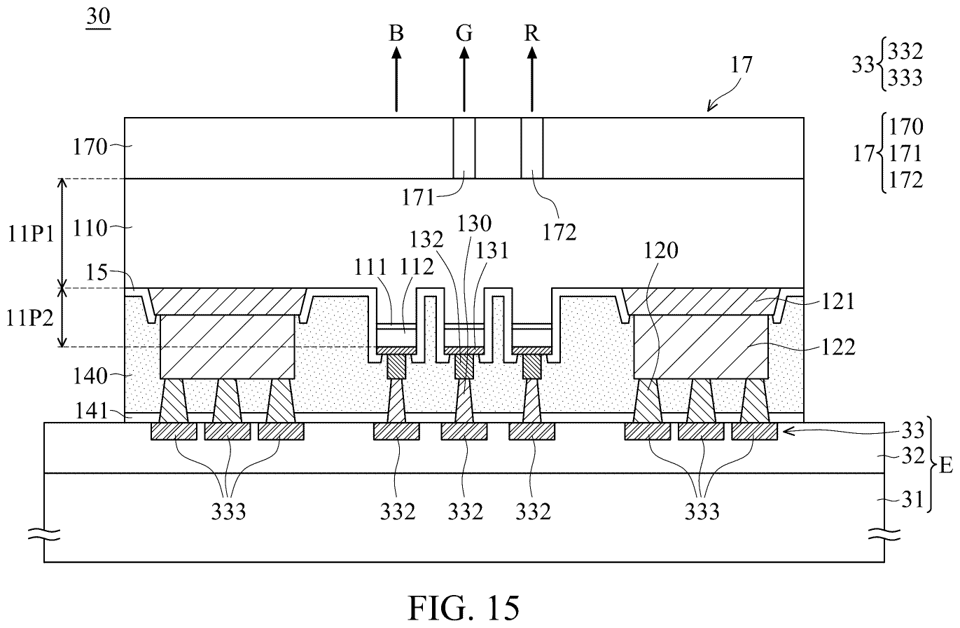

Thereby, when the semiconductor device 1g is subsequently bonded to the electronic device E (as shown in FIG. 15) through the second sublayer 141, the plurality of first conductive layers 120, and the plurality of third conductive layers 130, it may have good bonding yield. Similarly, the above-mentioned semiconductor devices 1b, 1c, 1c′, 1d, 1e, 1f, and the semiconductor device 1h described hereinafter may also be selected to have the above-mentioned characteristic.

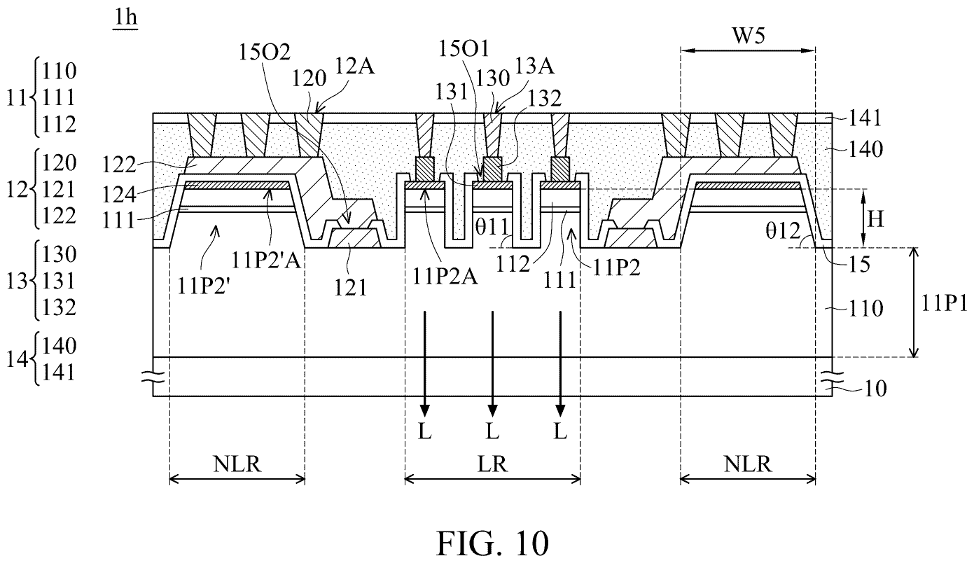

FIG. 10 is a cross-sectional view showing the semiconductor device 1h according to further embodiments of the present disclosure. The components and the connection relationship between components of the semiconductor device 1h is similar to that of the semiconductor device 1g in FIG. 9A. The main difference is that the semiconductor device 1h is further provided with the second portion 11P2′ under the fifth conductive layer 122, and the second conductive layer 121 is disposed between two adjacent second portions 11P2 and 11P2′. In detail, the semiconductor structure 11 of this embodiment includes the first portion 11P1 and the plurality of second portions 11P2 and 11P2′ on the first portion 11P1, wherein the plurality of second portions 11P2 and 11P2′ are divided into the light-emitting region LR and the non-light-emitting region NLR. The plurality of second portion 11P2 corresponds to the light-emitting region LR, and the second portion 11P2′ corresponds to the non-light-emitting region NLR.

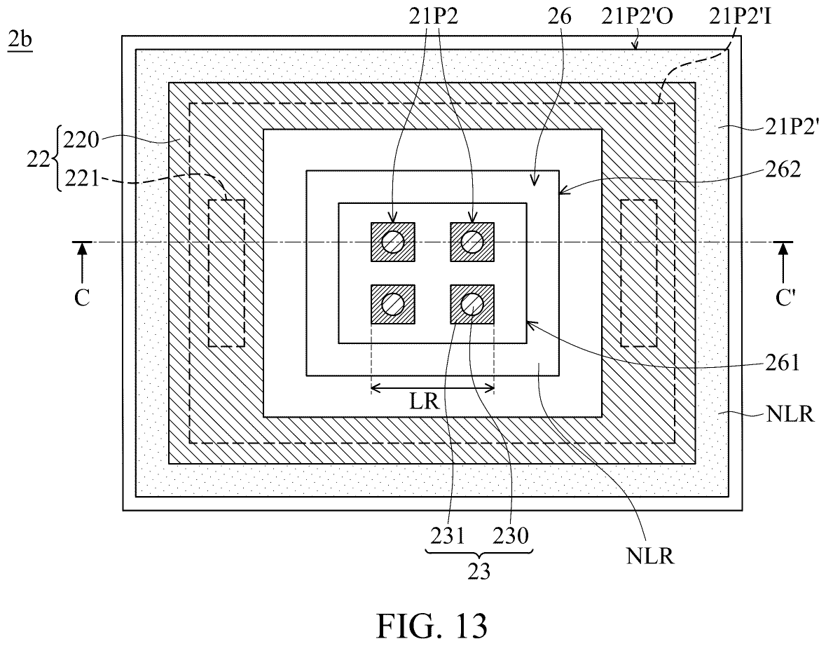

In some embodiments, the second portion 11P2 corresponding to the light-emitting region LR and the second portion 11P2′ corresponding to the non-light-emitting region NLR may be formed simultaneously in the same process. As mentioned above, the second portion 11P2 and the second portion 11P2′ include the first semiconductor layer 110, the active region 111 and the second semiconductor layer 112. In this embodiment, the second portion 11P2 and the second portion 11P2′ are separated and discontinuous from each other. In detail, the active region 111 and the second semiconductor layer 112 of the second portion 11P2 and the active region 111 and the second semiconductor layer 112 of the second portion 11P2′ are separated and discontinuous from each other. From a top view showing the semiconductor device 1h (not shown in the figure, however, the configurations of the light-emitting region LR and the non-light-emitting region NLR are similar to that of the semiconductor device 2b described hereinafter, and the top-view is as shown in FIG. 13), the non-light-emitting region NLR surrounds the light-emitting region LR, that is, the second portion 11P2′ surrounds the plurality of second portion 11P2.

From the cross-sectional view showing the semiconductor device 1h, as shown in FIG. 10, the light-emitting region LR is between the non-light-emitting regions NLR, wherein the fifth conductive layer 122 and the first conductive layer 120 locate in the non-light-emitting region NLR, and the third conductive layer 130, the fourth conductive layer 131, and the sixth conductive layer 132 locate in the light-emitting region LR. The second conductive layer 121 is disposed on the first portion 11P1 and is electrically connected to the first conductive layer 120. By disposing the second portions 11P2′ and 11P2 respectively under the outer electrode structure 12 and the inner electrode structure 13, the first top surface 12A and the second top surface 13A may be substantially coplanar, which is beneficial to the yield of the subsequent packaging bonding process.

In this embodiment, the seventh conductive layer 124 is optionally disposed between the second portion 11P2′ corresponding to the non-light-emitting region NLR and the insulating structure 15. In some embodiments, the fourth conductive layer 131 on the second portion 11P2 corresponding to the light-emitting region LR and the seventh conductive layer 124 on the second portion 11P2′ corresponding to the non-light-emitting region NLR may be formed simultaneously in the same process. Therefore, the material of the fourth conductive layer 131 of the inner electrode structure 13 may be the same as that of the seventh conductive layer 124.

The insulating structure 15 has a plurality of first openings 1501 on the second portions 11P2 corresponding to the light-emitting region LR and not corresponding to the second portion 11P2′ corresponding to the non-light-emitting area NLR. The second portion 11P2′ corresponding to the non-light-emitting area NLR is electrically insulated from the outer electrode structure 12 through the insulating structure 15. The insulating structure 15 also has a second opening 1502 on the second conductive layer 121. The sixth conductive layer 132 of the inner electrode structure 13 fills the first opening 1501 and is in contact with the fourth conductive layer 131, thereby being electrically connected to the second portion 11P2. The fifth conductive layer 122 of the outer electrode structure 12 fills the second opening 1502 and is in contact with the second conductive layer 121 on the first portion 11P1, thereby being electrically connected to the first portion 11P1.

In this embodiment, the second portion 11P2 corresponding to the light-emitting region LR and the second portion 11P2′ corresponding to the non-light-emitting region NLR have different shapes. From the cross-sectional view, the second portion 11P2′ has a trapezoidal shape that is narrow at the top and wide at the bottom, and the second portion 11P2 is a rectangular shape with equal width from top to bottom. An angle θ11 between the inner wall of the second portion 11P2 and the horizontal direction is between 75° and 90°, and an angle θ12 between the inner wall of the second portion 11P2′ and the horizontal direction is between 40° and 80°. The angle θ11 of the second portion 11P2 is greater than the included angle θ12 of the second portion 11P2′. When the height of the second portion 11P2 and the area of the top surface 11P2A are fixed, if the angle θ11 is less than 75°, the bottom of each second portion 11P2 (that is, where it is connected to the first portion 11P1) is too wide. Therefore, the quantity of the second portion 11P2 per unit area will be too small, which will further reduce the resolution of the product. If the angle θ11 is greater than 90°, the second portion 11P2 forms an inverted trapezoidal shape with a wide top and a narrow bottom, which is not easy to dispose the insulating structure 15 on the second portion 11P2. In other embodiments, the second portion 11P2 corresponding to the light-emitting region LR and the second portion 11P2′ corresponding to the non-light-emitting region NLR may have the same shape.

In the case where the second portion 11P2′ corresponding to the non-light-emitting region NLR maintains a certain height H and a certain area of the top surface 11P2′A, if the angle θ12 is less than 40°, a width W5 of the second portion 11P2′ is too wide. Therefore, the manufacture process is difficult to performed. For example, the space between the second portion 11P2′ and the adjacent second portion 11P2 will be too small, thereby reducing the process window of disposing the second conductive layer 121. On the contrary, if the included angle θ12 is greater than 70°, the side walls of the second portion 11P2′ is too vertical, thereby worsening the covering integrity of the outer electrode structure 12.

In addition to the shape, the difference between the second portion 11P2 corresponding to the light-emitting region LR and the second portion 11P2′ corresponding to the non-light-emitting region NLR are that the insulating structure 15 completely covers the seventh conductive layer 124 of the second portion 11P2′ corresponding to the non-light-emitting region NLR. Moreover, the insulating structure 15 has a plurality of first openings 1501 that expose the fourth conductive layers 131 of the inner electrode structure 13 on the second portion 11P2 corresponding to the light-emitting region LR. In this case, the second portion 11P2 corresponding to the light-emitting region LR may be electrically connected to other electronic devices through the fourth conductive layer 131. When the semiconductor device 1h operates, the second portion 11P2 may be turned on and emit light. On the contrary, the second portion 11P2′ cannot be electrically connected to other electronic devices through the seventh conductive layer 124. When the semiconductor photovoltaic element 1h operates, the second portion 11P2′ does not emit light.

As mentioned above, the top surface 11P2A of the second portion 11P2 corresponding to the light-emitting region LR and the top surface 11P2′A of the second portion 11P2′ corresponding to the non-light-emitting region NLR are substantially coplanar by disposing the second portion 11P2′ in the non-light-emitting region NLR. In addition, the outer electrode structure 12 is disposed on the second portion 11P2′, so that the first top surface 12A and the second top surface 13A are substantially coplanar. However, in other embodiments, the second portion 11P2′ may be replaced with other components, such as a raising layer disposed between the first portion 11P1 and the outer electrode structure 12, to achieve the same purpose. The material of the raising layer may be an insulating material.

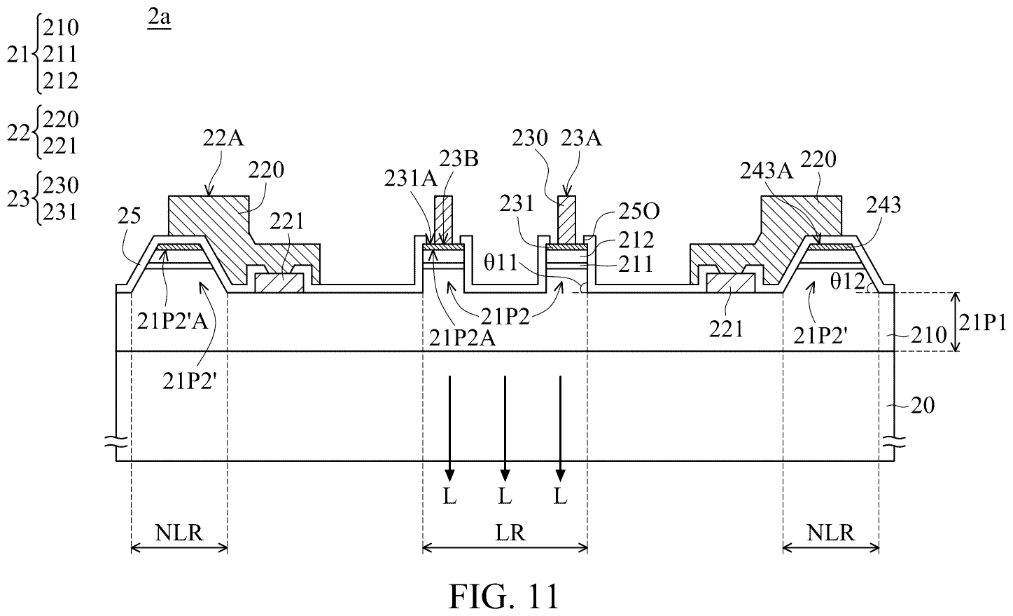

FIG. 11 is a cross-sectional view showing the semiconductor device 2a according to further embodiments of the present disclosure. In this embodiment, the semiconductor device 2a may be a semiconductor device that uses a mass transfer process to be electrically connected to a circuit. The components and the connection relationship between components of the semiconductor device 2a is similar to that of the semiconductor device 1h in FIG. 10. The difference is that the semiconductor device 2a does not have the above-mentioned adjustment structure, fifth conductive layer, and sixth conductive layer. In detail, the semiconductor device 2a includes a substrate 20, a semiconductor structure 21, an outer electrode structure 22, an inner electrode structure 23, and an insulating structure 25. The first top surface 22A of the outer electrode structure 22 is substantially coplanar with the second top surface 23A of the inner electrode structure 23. In these embodiments, the substrate 20, the semiconductor structure 21, the outer electrode structure 22, the inner electrode structure 23, and the insulating structure 25 may be similar or identical to the above-mentioned substrate 10, semiconductor structure 11, outer electrode structure 12, inner electrode structure 13, and insulating structure 15, respectively. The detailed description can be referred to the mentioned above and is omitted here.

In this embodiment, the first conductive layer 220 is on the second conductive layer 221 and covers the side surface and the top surface of the second portion 21P2′. By using the second portion 21P2′ as a step, the first top surface 22A of the outer electrode structure 22 on the second portion 21P2′ (that is, the top surface of the first conductive layer 220) may be substantially coplanar with the second top surfaces 23A of the inner electrode structure 23 (that is, the top surface of the third conductive layer 230). In this way, in the subsequent mass transfer process, the first top surface 22A of the outer electrode structure 22 and the second top surface 23A of the inner electrode structure 23 have the same height, thereby achieving good and stable electrical connection with other electronic devices. In some embodiments, the metal thicknesses of the first conductive layer 220 and the third conductive layer 230 may be the same or different, or the first conductive layer 220 and the third conductive layer 230 may be formed by different processes or methods. In another embodiment, the first top surface 22A is slightly lower than the second top surface 23A. For example, in one embodiment, the first top surface 22A is 0.1 μm to 0.5 μm lower than the second top surface 23A.

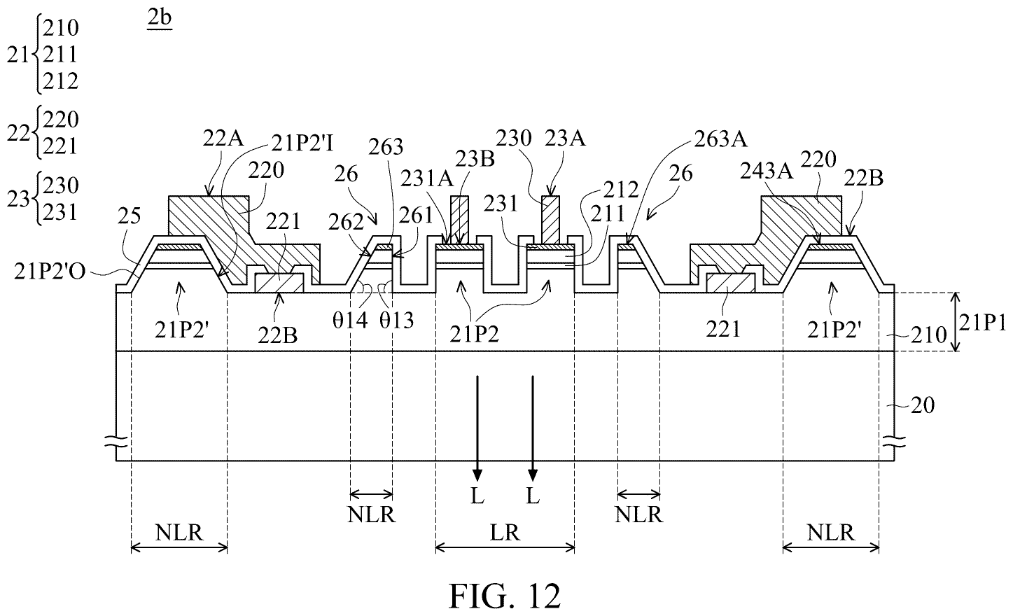

FIGS. 12 and 13 are a cross-sectional view and a top view showing the semiconductor device 2b according to further embodiments of the present disclosure. FIG. 12 is a cross-sectional view along line C-C′ in FIG. 13. Compared with the embodiment in FIG. 11, the semiconductor device 2b in FIGS. 12 and 13 further includes the barrier structure 26.

As shown in FIG. 13, the second portion 21P2′ surrounds the plurality of second portion 21P2. Specifically, the second portion 21P2′ has an inner wall 21P2′I and an outer wall 21P2′O, and both the inner wall 21P2′I and the outer wall 21P2′O are outside the second portion 21P2, so that the second portion 21P2′ surrounds the second portion 21P2. On the other hand, the barrier structure 26 surrounds the inner electrode structure 23. Specifically, the barrier structure 26 has a first side wall 261 and a second side wall 262 (which will be further described below), and the first side wall 261 and the second side wall 262 are both outside the inner electrode structure 23, so that the barrier structure 26 surrounds the inner electrode structure 23. The outer electrode structure 22 surrounds the barrier structure 26. In detail, the barrier structure 26 is between the outer electrode structure 22 and the inner electrode structure 23. In this embodiment, as shown in FIG. 13, the outer electrode structure 22, the second portion 21P2′, and the barrier structure 26 are all annular.

In this embodiment, the barrier structure 26 includes the first semiconductor layer 210, the active region 211, the second semiconductor layer 212, and the eighth conductive layer 263 stacked in sequence. In this embodiment, although the second portion 21P2, the second portion 21P2′, and the barrier structure 26 all have the first semiconductor layer 210, the active region 211, and the second semiconductor layer 212, the shapes of the three are different from one other. For example, the second portion 21P2 is a rectangle with equal width, the second portion 21P2′ is a symmetrical trapezoid, and the barrier structure 26 is an asymmetrical trapezoid. More specifically, the two side walls 261,262 of the barrier structure 26 in this embodiment are not parallel to each other, and one of the side walls is parallel to the normal direction of the substrate 10. As shown in FIG. 12, in detail, the barrier structure 26 includes a first side wall 261 and a second side wall 262 farther away from the light-emitting region LR than the first side wall 261. There is an angle θ13 between the first side wall 261 and the horizontal direction and an angle θ14 between the second side wall 262 and the horizontal direction that is different from the angle θ13. In this embodiment, the angle 014 is smaller than the angle θ13. For example, the angle θ13 is between 75° and 90°, and the angle θ14 is between 40° and 70°.

Same as the second portion 21P2′, the barrier structure 26 corresponds to the non-light-emitting region NLR. Specifically, the insulating structure 25 completely covers the eighth conductive layer 263 on the barrier structure 26, and the insulating structure 25 exposes the fourth conductive layer 231 of the inner electrode structure 23 on the second portion 21P2. In this case, the barrier structure 26 cannot be electrically connected to other electronic devices through the eighth conductive layer 263. When the semiconductor device 2b is operating, the barrier structure 26 does not emit light.

In some embodiments, the second portion 21P2 and the barrier structure 26 may be formed simultaneously in the same process. Since the second portion 21P2 and the barrier structure 26 are separated from each other, the active region 211 in the second portion 21P2 and the active region 211 in the barrier structure 26 are separated from each other and the active regions 211 are discontinuous.

In some embodiments, the fourth conductive layer 231 on the second portion 21P2 corresponding to the light-emitting region LR and the eighth conductive layer 263 on the barrier structure 26 may be formed simultaneously in the same process. Therefore, the fourth conductive layer 231 of the inner electrode structure 23 and the eighth conductive layer 263 of the barrier structure 26 may have the same material.

As mentioned above, the top surface 231A corresponding to the second portion 21P2 corresponding to the light-emitting region LR and the top surface 263A of the eighth conductive layer 263 of the barrier structure 26 are substantially coplanar.

Physical isolation and electrical isolation may be formed between the outer electrode structure 22 and the inner electrode structure 23 by providing the barrier structure 26. In detail, since there is the barrier structure 26 between the outer electrode structure 22 and the inner electrode structure 23, when the semiconductor device 2b is bonded with other electronic devices (such as CMOS), it may prevent the outer electrode structure 22 and the inner electrode 23 structure from a short circuit with each other.

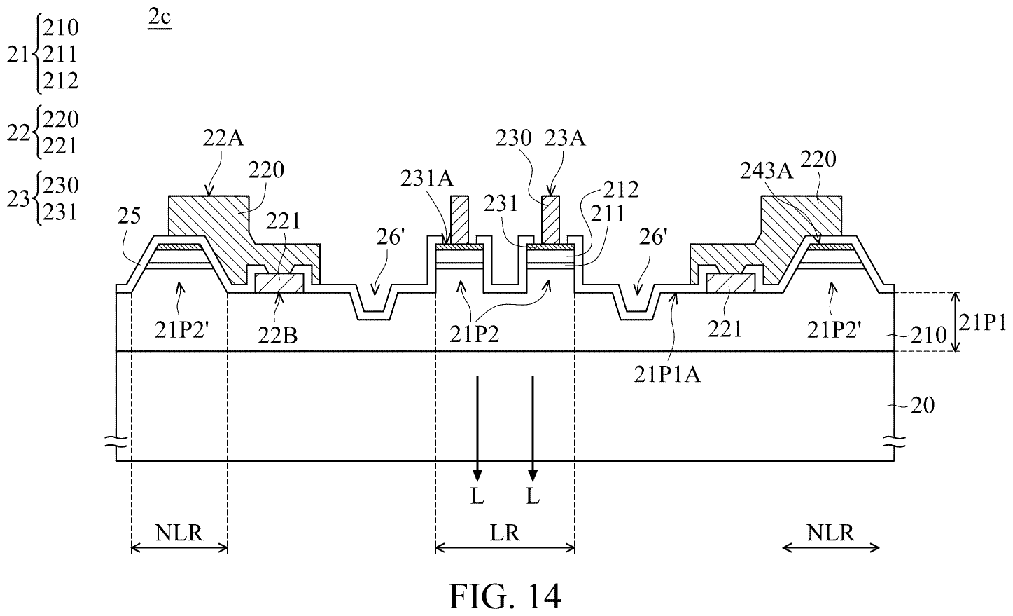

FIG. 14 is a cross-sectional view showing the semiconductor device 2c according to further embodiments of the present disclosure. Compared with the embodiments in FIGS. 12 and 13, the barrier structure 26′ of the semiconductor device 2c in FIG. 14 is a recess, which is recessed from the top surface 21P1A of the first portion 21P1 toward the substrate 20. By providing the barrier structure 26′, physical isolation and electrical isolation may be formed between the outer electrode structure 22 and the inner electrode structure 23. When the semiconductor device 2c is connected to other electronic devices (such as CMOS), it may prevent the outer electrode structure 22 and the inner electrode structure 23 from a short circuit with each other.

FIG. 15 is a cross-sectional view showing the semiconductor apparatus 30 according to further embodiments of the present disclosure. The semiconductor apparatus 30 includes a semiconductor device and the electronic device E. The semiconductor device may be the above-mentioned semiconductor device 1a-1h, or 2a-2c, and the semiconductor device may have the substrate 10 or the substrate 20. Alternatively, the substrate 10 or the substrate 20 may be omitted as required. In this embodiment, the semiconductor device is similar to the semiconductor device 1g shown in FIG. 9A, except that it does not have the substrate 10. The electronic device E such as CMOS, includes the substrate 31, the dielectric layer 32 on the substrate 31, and the electrical connection structure 33 in the dielectric layer 32 or embedded in the dielectric layer 32. The electrical connection structure 33 includes the plurality of first connection parts 332 and the plurality of second connection parts 333. The electronic device E is electrically and physically connected to the plurality of third conductive layers 130 through the plurality of first connection parts 332, and is electrically and physically connected to the plurality of first conductive layers 120 through the plurality of second connection parts 333. The dielectric layer 32 is connected to the second sublayer 141. In this embodiment, the semiconductor device 30 further includes the wavelength conversion structure 17 on the first semiconductor layer 110, wherein the wavelength conversion structure 17 includes the base part 170 and the plurality of wavelength conversion portions 171 and 172 in the base part 170, and each wavelength conversion part 171 and 172 is aligned with each second portion 11P2. For example, the semiconductor device in this embodiment may emit blue light and includes three of the second portions 11P2. The wavelength conversion parts 171 and 172 correspond to two of the second portions 11P2, so as to respectively convert the light emitted from the second portions 11P2 into red light and green light. The other second portion 11P2 does not have a corresponding wavelength conversion part, therefore it emits the original blue light. In this way, the electronic device E may be used to drive the semiconductor device to emit light, and three light with different wavelengths are generated through the wavelength conversion structure 17 and emitted from the semiconductor device 30.

In this embodiment, the dielectric layer 32 and the second sublayer 141 may have the same material, such as silicon dioxide, the first connection part 332 and the third conductive layer 130 may have the same material, such as copper, and the second connection part 333 and the first conductive layer 120 may have the same material such as copper. When connecting the semiconductor device and the electronic device E, a two-stage bonding process may be performed. For example, the first stage is pressurizing to make the dielectric layer 32 and the second sublayer 141 align and adhere to each other. The second stage is heating to make the first connection part 332 and the third conductive layer 130 produce a phase change to be fused and butted, and make the second connection part 333 and the first conductive layer 120 produce a phase change to be fused and butted, thereby increasing the alignment accuracy, and improving the production yield of the semiconductor device 30 with the electronic device E.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a semiconductor structure comprising a first portion and a second portion on the first portion, wherein the second portion comprises an active region;
an outer electrode structure on the first portion of the semiconductor structure and having a first top surface;
an inner electrode structure on the second portion of the semiconductor structure and having a second top surface; and
an adjustment structure covering the semiconductor structure and having a third top surface, and the adjustment structure being in contact with the outer electrode structure and the inner electrode structure;
wherein the first top surface and the third top surface are substantially coplanar, and/or the second top surface and the third top surface are substantially coplanar.

2. The semiconductor device as claimed in claim 1, wherein the outer electrode structure surrounds the inner electrode structure from a top view of the semiconductor device.

3. The semiconductor device as claimed in claim 1, wherein the outer electrode structure comprises a first conductive layer and a second conductive layer between the first conductive layer and the first portion, and the inner electrode structure comprises a third conductive layer and a fourth conductive layer between the third conductive layer and the second portion.

4. The semiconductor device as claimed in claim 1, wherein the semiconductor structure comprises a plurality of second portions and the inner electrode structure comprises a plurality of third conductive layer respectively located on the plurality of second portions.

5. The semiconductor device as claimed in claim 1, wherein the outer electrode structure comprises a second conductive layer and a plurality of first conductive layer on the second conductive layer.

6. The semiconductor device as claimed in claim 1, wherein the semiconductor device emits a light away from the inner electrode structure.

7. The semiconductor device as claimed in claim 1, wherein the outer electrode structure comprises a plurality of first conductive layers, and/or the inner electrode structure comprises a plurality of third conductive layers,

8. The semiconductor device as claimed in claim 7, wherein each of the plurality of first conductive layers has a first top view area, and each of the plurality of third conductive layers has a second top view area that is substantially equal to the first top view area.

9. The semiconductor device as claimed in claim 1, wherein the adjustment structure comprises a first sublayer and a second sublayer on the first sublayer.

10. The semiconductor device as claimed in claim 9, wherein the first sublayer comprises a hardness or a Young's modulus, different from a hardness or a Young's modulus of the second sublayer.

11. The semiconductor device as claimed in claim 1, further comprising an insulating structure disposed between the semiconductor structure and the adjustment structure.

12. The semiconductor device as claimed in claim 11, wherein the insulating structure comprises a metallic reflective layer.

13. The semiconductor device as claimed in claim 12, wherein the insulating structure further comprises a first insulating layer and a second insulating layer, and the metallic reflective layer locates between the first insulating layer and the second insulating layer.

14. The semiconductor device as claimed in claim 1, wherein the first top surface and/or the second top surface each have a concave morphology.

15. A semiconductor device, comprising:
a semiconductor structure comprising a first portion and a plurality of second portions on the first portion, a light-emitting region and a non-light-emitting region, wherein each of the plurality of second portions comprises an active region, and one of the plurality of second portions corresponding to the light-emitting region and one of the plurality of second portions corresponding to the non-light-emitting region;
an outer electrode structure on the one of the plurality of second portions corresponding to the non-light-emitting region and extending to cover the first portion, wherein the outer electrode structure has a first top surface; and
an inner electrode structure on the one of the plurality of the second portions corresponding to the light-emitting region, wherein the inner electrode structure has a second top surface substantially coplanar with the first top surface

16. The semiconductor device as claimed in claim 15, wherein the outer electrode structure comprises a first conductive layer and a second conductive layer between the first conductive layer and the first portion.

17. The semiconductor device as claimed in claim 16, further comprising an insulating structure between the first conductive layer and the second conductive layer.

18. The semiconductor device as claimed in claim 15, further comprising a barrier structure between the light-emitting region and the non-light-emitting region, and the barrier structure comprises the active region.

19. The semiconductor device as claimed in claim 18, wherein the barrier structure surrounds the inner electrode structure, and the outer electrode structure surrounds the barrier structure from a top view of the semiconductor device.

20. The semiconductor device as claimed in claim 18, wherein the barrier structure comprises a first side wall and a second side wall farther away from the light-emitting region than the first side wall, and the first side wall has a first angle, and the second side wall has a second angle smaller than the first angle.
